(19) United States
(12) Patent Application Publication
(10) Pub. No.: US 2026/0303085 A1
(43) Pub. Date: Oct. 1, 2026

(54) METHODS AND APPARATUS FOR REDUCING LEAKAGE CURRENTS IN CMOS

(71) Applicant: QUALCOMM Incorporated, San Diego, CA (US)

(72) Inventors: Rama Narendra Kumar BODDU, Bangalore (IN); Asheesh Singh Baghel, Bangalore (IN); Mayank Aswal, Bengaluru (IN); Amit Duggal, Bangalore (IN); Nitin Jaiswal, Bangalore (IN)

(21) Appl. No.: 19/091,457

(22) Filed: Mar. 26, 2025

(51) Int. Cl. H03K 17/16; H03K 19/21

(52) U.S. Cl. CPC H03K 17/161; H03K 19/21

(57) ABSTRACT

Aspects of the present disclosure include methods for reducing leakage current including identifying a commutative circuit of a plurality of circuits, the commutative circuit being configured to receive a first logical input signal via a first terminal and a second logical input signal via a second terminal, identifying a first leakage current associated with a first state of the commutative circuit and a second leakage current associated with a second state of the commutative circuit, the first leakage current being larger than the second leakage current, and switching, at a software level, the first logical input signal and the second logical input signal such that the commutative circuit receives the first logical input signal via the second terminal and the second logical input signal via the first terminal.

### BACKGROUND

Aspects of the present disclosure relate generally to wireless communications, and more particularly, to apparatuses and methods for reducing leakage currents in complementary metal oxide silicon (CMOS) field effect transistor (FET) circuits.

Integrated circuit (IC) chips are used pervasively in multiple applications, ranging from wireless communication to automotive operations. Modern CMOS based IC chips may each include thousands or even millions of MOSFETs. However, each MOSFET may contribute to leakage currents. The leakage currents may be caused by various factors, such as leakage across the gate, through the channel, or into the body. These leakage currents can cause unwanted heating of the IC chips, slowing of the IC chips operations, and/or reduction of battery charges. Therefore, reduction of leakage currents is desirable.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

Aspects of the present disclosure include methods for reducing leakage current including identifying a commutative circuit of a plurality of circuits, the commutative circuit being configured to receive a first logical input signal via a first terminal and a second logical input signal via a second terminal, identifying a first leakage current associated with a first state of the commutative circuit and a second leakage current associated with a second state of the commutative circuit, the first leakage current being larger than the second leakage current, and switching, at a software level, the first logical input signal and the second logical input signal such that the commutative circuit receives the first logical input signal via the second terminal and the second logical input signal via the first terminal.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 is an example of circuit diagrams illustrating operations of a commutative circuit according to aspects of the present disclosure;

FIG. 2 is an example of a layout of the commutative circuit according to aspects of the present disclosure;

FIG. 3 is an example of a method for reducing leakage current according to aspects of the present disclosure;

FIG. 4 is an example of a system for implementing the scheme of leakage reduction according to aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Several aspects of telecommunication systems will now be presented with reference to various apparatus and methods. These apparatus and methods will be described in the following detailed description and illustrated in the accompanying drawings by various blocks, components, circuits, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented as a “processing system” that includes one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Accordingly, in one or more example embodiments, the functions described may be implemented in hardware, software, or any combination thereof. If implemented in software, the functions may be stored on or encoded as one or more instructions or code on a computer-readable medium. Computer-readable media includes computer storage media. Storage media may be any available media that may be accessed by a computer. By way of example, and not limitation, such computer-readable media may comprise a random-access memory (RAM), a read-only memory (ROM), an electrically erasable programmable ROM (EEPROM), optical disk storage, magnetic disk storage, other magnetic storage devices, combinations of the aforementioned types of computer-readable media, or any other medium that may be used to store computer executable code in the form of instructions or data structures that may be accessed by a computer.

Aspects of the present disclosure relate to leakage reduction in CMOS circuits. Automotive products operate at higher worst-case temperatures (e.g., up to 140° C.) compared to some other applications. At lower driving voltage, specially at higher temperatures, leakage contributions is as significant as dynamic power. Automotive products also implement additional infield testing (e.g., MBIST, XLBIST, STL, etc.), which could send the IC chip to functionally idle state more frequently. These all contribute to increasing leakage currents in CMOS circuits.

There are existing techniques for leakage optimization. However, existing leakage optimization may be limited to techniques such as lowering the operating voltage, reducing transistor sizes, and/or power-gating the chips. Further, the power-down sequence requires idle time (i.e., hysteresis counter to expire) after workload completion, and similarly power-up sequence latency for reliable power-up also generates leakage current in functionally idle state. Functional safety testing requirement also limits the number of hardware controlled low power modes in automotive applications. Aspects of the present disclosure relates to reducing leakage current.

An aspect of the present disclosure includes identifying a difference in channel leakage currents between a first state of a CMOS circuit and a second state of the CMOS circuit. Specifically, an aspect of the present disclosures includes identifying the difference in channel leakage currents that is caused by an asymmetry of leakage currents of two logical states due to the voltage differences across the drain terminals and the source terminals of MOSFETs of the CMOS circuit associated with the logical states. The voltage differences across the drain terminals and the source terminals may be caused by various factors such as voltage drop across metal/polysilicon contact lines. In certain aspects, the leakage currents may include currents leaking through the channel of the MOSFETs due to reverse-biased PN junction at the contacts, subthreshold leakage, threshold voltage roll off induced leakage, drain induced barrier lowering, and/or channel punch-through. In some aspects, the leakage currents may occur when the MOSFETs are operating in the subthreshold regime of operation (i.e., when the gate voltage is below the threshold voltage that turns the MOSFETs on).

An aspect of the present disclosure includes identifying leakage currents for various logical states of a CMOS circuit. The logical states may be altered to minimize the leakage currents. In one aspect, if a first logical state of a CMOS circuit has a higher leakage current than that of a second logical state, and the first logical state occurs more frequently than the second logical state, the inputs of the CMOS circuit may be switched so that the second logical state occurs more frequently than the first logical state.

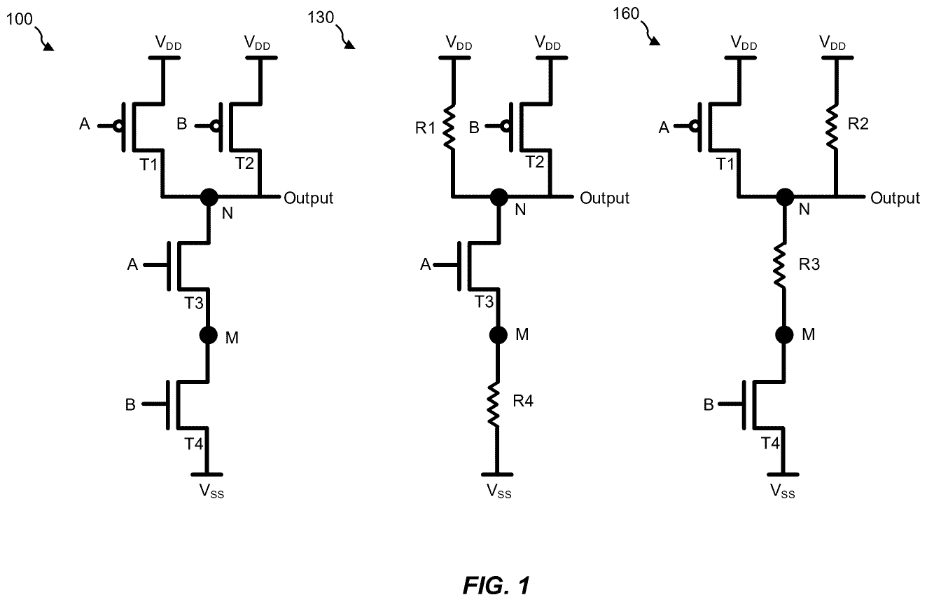

FIG. 1 is a schematic diagram of circuit operations according to various aspects of the present disclosure. FIG. 1 shows a first circuit diagram 100. The first circuit diagram 100 shows a NOT AND (NAND) gate. The NAND gate may include a first p-type metal-oxide-semiconductor (MOS) field effect transistor (P-MOSFET) T1, a second P-MOSFET T2, a first n-type MOSFET (N-MOSFET) T3, and a second N-MOSFET T4. The gates of T1 and T3 are connected to a first input A, which represents a first logical input. The gates of T2 and T4 are connected to a second input B, which represents a second logical input that may be the same or different than the first logical input.

In some aspects, the NAND gate operates as follows. The NAND gate may be connected to, and/or powered by, a high supply voltage (V_{DD}) and a low supply voltage (V_{SS}). In a first operational state, a logical “high” voltage (representing a first logical input) may appear on the first input A. As such, a logical “high” voltage may be applied to the gates of T1 and T3. Since T1 is a P-MOSFET and T3 is a N-MOSFET, the logical “high” voltage will turn off T1 and turn on T3.

Further, a logical “low” voltage (representing a second logical input) may appear on the second input B. As such, a logical “low” voltage may be applied to the gates of T2 and T4. Since T2 is a P-MOSFET and T4 is a N-MOSFET, the logical “low” voltage will turn on T2 and turn off T4. In response to the logical “high” voltage on the first input A and the logical “low” voltage on the second input B, the output terminal of the NAND gate may output a high output voltage.

In a second operational state, a logical “high” voltage may appear on the first input A. As such, a logical “high” voltage may be applied to the gates of T1 and T3. Since T1 is a P-MOSFET and T3 is a N-MOSFET, the logical “high” voltage will turn off T1 and turn on T3.

Further, a logical “high” voltage may appear on the second input B. As such, a logical “high” voltage may be applied to the gates of T2 and T4. Since T2 is a P-MOSFET and T4 is a N-MOSFET, the logical “high” voltage will turn off T2 and turn on T4. In response to the logical “high” voltage on the first input A and the logical “high” voltage on the second input B, the output terminal of the NAND gate may output a low output voltage.

In a third operational state, a logical “low” voltage may appear on the first input A. As such, a logical “low” voltage may be applied to the gates of T1 and T3. Since T1 is a P-MOSFET and T3 is a N-MOSFET, the logical “low” voltage will turn on T1 and turn off T3.

Further, a logical “high” voltage may appear on the second input B. As such, a logical “high” voltage may be applied to the gates of T2 and T4. Since T2 is a P-MOSFET and T4 is a N-MOSFET, the logical “high” voltage will turn off T2 and turn on T4. In response to the logical “low” voltage on the first input A and the logical “high” voltage on the second input B, the output terminal of the NAND gate may output a high output voltage.

In a fourth operational state, a logical “low” voltage may appear on the first input A. As such, a logical “low” voltage may be applied to the gates of T1 and T3. Since T1 is a P-MOSFET and T3 is a N-MOSFET, the logical “low” voltage will turn on T1 and turn off T3.

Further, a logical “low” voltage may appear on the second input B. As such, a logical “low” voltage may be applied to the gates of T2 and T4. Since T2 is a P-MOSFET and T4 is a N-MOSFET, the logical “low” voltage will turn on T2 and turn off T4. In response to the logical “low” voltage on the first input A and the logical “low” voltage on the second input B, the output terminal of the NAND gate may output a high output voltage. The truth table for the NAND gate is shown below.

| Input A | Input B | Output |
|---|---|---|
| High | Low | High |
| High | High | Low |
| Low | High | High |
| Low | Low | High |

The true table above may be expressed in binary form for digital logic.

| Input A | Input B | Output |
|---|---|---|
| 1 | 0 | 1 |
| 1 | 1 | 0 |
| 0 | 1 | 1 |
| 0 | 0 | 1 |

FIG. 1 shows a second circuit diagram 130 illustrating the states of the NAND gate during the third operation state. Here, a logical “low” voltage is applied to the first input A and the logical “high” voltage is applied to the second input B. In response to the logical “low” voltage on T1, the channel of T1 is turned on, and may behave as a resistor R1. In response to the logical “high” voltage on T4, the channel of T4 is turned on, and may behave as a resistor R4. Here, T2 and T3 remain off.

In the second circuit diagram 130 (during the third operation state), a current may flow from V_{DD} toward the output terminal via R1 (channel of T1 during on state). However, a voltage difference V_{DS}(T3) may appear across T3. The voltage difference V_{DS}(T3) may be (V_{N}−V_{M}), where V_{N} is less than V_{DD} and V_{M} is greater than V_{SS}. As such, a leakage current I_{D-Leakage}(T3) through the channel of T3 may occur. The magnitude of the leakage I_{D-Leakage}(T3) current may depend on the magnitude of V_{DS}(T3). Specifically, the leakage current I_{D-Leakage}(T3) may depend on V_{DS}(T3) linearly, quadratically, or exponentially.

FIG. 1 shows a third circuit diagram 160 illustrating the states of the NAND gate during the first operation state. Here, a logical “high” voltage is applied to the first input A and the logical “low” voltage is applied to the second input B. In response to the logical “low” voltage on T2, the channel of T2 is turned on, and may behave as a resistor R2. In response to the logical “high” voltage on T3, the channel of T3 is turned on, and may behave as a resistor R3. Here, T1 and T4 remain off.

In the third circuit diagram 160 (during the first operation state), a current may flow from V_{DD} toward the output terminal via R2 (channel of T2 during on state). However, a voltage difference V_{DS}(T4) may appear across T4. The voltage difference V_{DS}(T4) may be (V_{M}−V_{SS}), where V_{M} is less than V_{DD}. As such, a leakage current I_{D-Leakage}(T4) through the channel of T4 may occur. The magnitude of the leakage current I_{D-Leakage}(T4) may depend on the magnitude of V_{DS}(T4). Specifically, the leakage current I_{D-Leakage}(T4) may depend on V_{DS}(T4) linearly, quadratically, or exponentially.

Aspects of the present disclosure include identifying a difference in the leakage currents I_{D-Leakage}(T3) and I_{D-Leakage}(T4) as explained below.

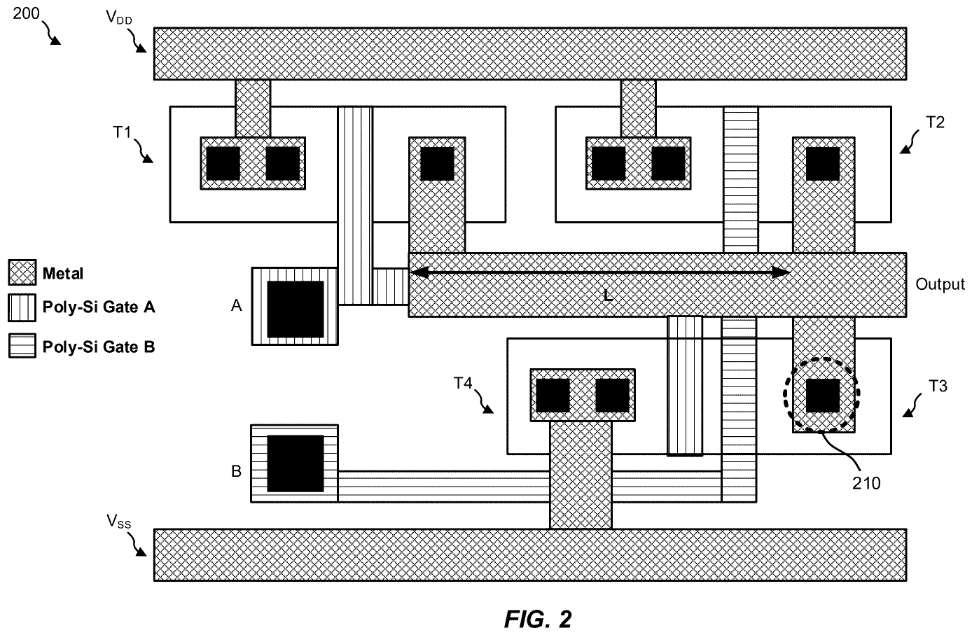

FIG. 2 illustrates an example of a layout 200 for the NAND gate shown in FIG. 1. Referring to FIGS. 1 and 2, in some aspects of the present disclosure, the layout 200 shows the asymmetry in conduction paths between T1 to the output and between T2 to the output. Specifically, during the third operation state shown in the second circuit diagram 130, the driving current flows from V_{DD} toward the output terminal via T1. On the contrary, during the first operation state shown in the third circuit diagram 160, the driving current flows from V_{DD} toward the output terminal via T2. Consequently, the driving current through T1 (during the third operation state) has to flow through a longer (by L) portion of the metal, as compared to the driving current through T2 (during the first operation state). As such, even though in PMOSFETs T1 and T2 both provide driving currents (separately in the third operation state and the first operation state, respectively), the voltage at the drain terminal of T3 (dotted circle labeled as 210) will be different due to the resistivity of the metal interconnect. Assuming the channel resistances of T3 and T4 (i.e., R3 and R4) are identical, V_{DS}(T3) during the third operation state will be larger than V_{DS}(T4) during the first operation state. As a result, I_{D-Leakage}(T3) through T3 during the third operation state will be larger than I_{D-Leakage}(T4) during the first operation state.

Aspects of the present disclosure includes identifying the asymmetry above in a CMOS circuit. In response to identifying the asymmetry, aspects of the present disclosure include switching the logical inputs (A becomes B and B becomes A) such that the third operation state switches with the first operation state. After the switch of the operation states, the overall leakage current of the CMOS circuit will decrease due to the asymmetry described above. Here, the “switching” occurs at the software level, meaning that there are no rewiring of redesign of the circuits/layouts. Instead, aspects of the present disclosure include changing the first logical value at a first input terminal of the circuit into the second logical value at a second input terminal of the circuit, and vice versa. As such, the circuit design and layout remain the same while leakage current is reduced.

In other words, aspects of the present disclosure include configuring the logical input values of a circuit so that a logical “off” or “subthreshold” state of a transistor occurs more often at a transistor with lower subthreshold leakage.

In one aspect of the present disclosure, the scheme described above is demonstrated on a NAND gate. However, the scheme is applicable to any commutative circuit, which is defined as a circuit that outputs the same result in response to the inputs being A and B or B and A. In other words, if A and B are inputted into a circuit and the result is C, and if B and A are inputted into the same circuit and the result is still C, the circuit is commutative. Examples of commutative circuits include AND gates, OR gates, NAND gates, NOR gates, and EXCLUSIVE OR (XOR) gates. Additional examples of commutative circuits may also include certain circuits implemented by one or more of the gates indicated above, such as adders and multipliers. Other commutative circuits may also implement the scheme of the present disclosure.

In some aspects, the scheme described above is demonstrated on CMOS circuits. However, circuits with other transistor technology may also implement this scheme. For example, the leakage mitigation scheme above may be applicable to circuits with one or more of MOSFETs, bi-polar junction transistors (BJTs), metal-semiconductor field effect transistors (MESFETs), junction field effect transistors (JFETs), or other types of transistors.

Aspects of the present disclosure includes many advantages. For example, there is a reduced silicon on chip supported sleep states in automotive devices than in certain other applications. As such, there are limited power saving opportunities with driving voltage reduction in idle states. While low power sleep modes may be implemented using software control with high latency along with extended idle times, the combination of extended idle windows and high latency may result in devices wasting energy via leakage power. Similar latencies may occur during power-on, which also causes idle leakage.

In some instances, certain applications require more frequent testing of the chips (e.g., for functional safety purposes). As such, many of the circuits may hover in idle states during the testing. Therefore, aspects of the present disclosure reduces energy consumption, heat generation, and/or circuit performance by reducing idle state leakage.

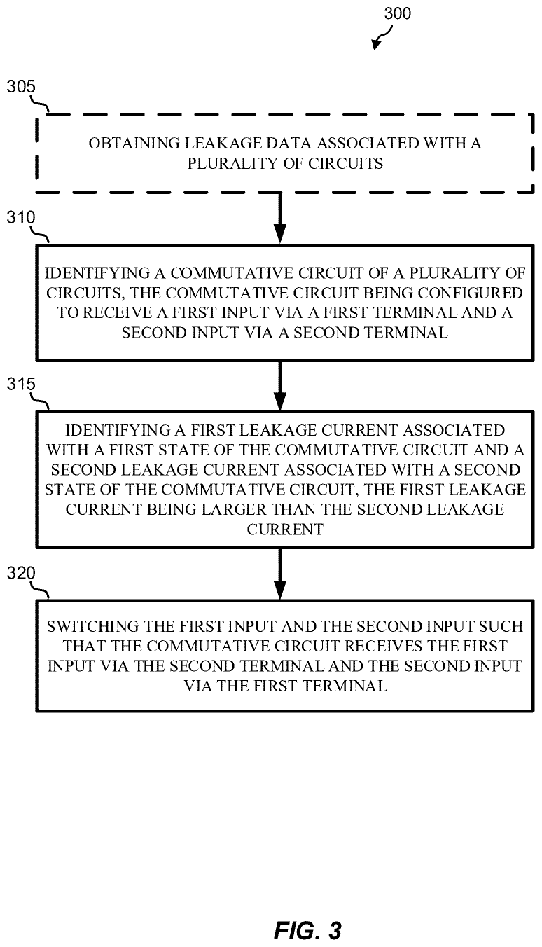

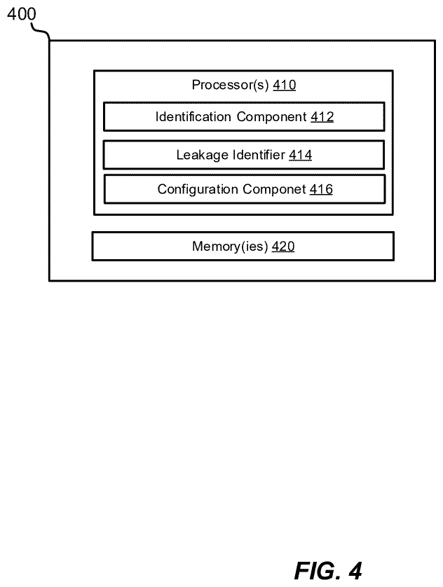

FIG. 3 illustrates an example of a method 300 for implementing the leakage reduction scheme according to certain aspects of the present disclosure. The method 300 may be performed by one or more components of a system 400 (FIG. 4). The system 400 may include one or more processors 410 and/or one or more memories 420. For example, the method 300 may be performed by the one or more processors 410 configured to read data stored in the one or more memories 420 and/or execute one or more instructions stored in the one or more memories 420 of the system. The method 300 may be performed by an identification component 412 configured to identify a commutative circuit. The method 300 may be performed by a leakage identifier 414 configured to identify leakage currents in a circuit. The method 300 may be performed by a configuration component 416 configured to reconfigure the logical input values to a circuit as described above.

At block 305, the method 300 may optionally obtain leakage data associated with a plurality of circuits. For example, the system 400, the one or more processors 410 may generate state-level leakage data look-up tables for each library circuit based on data stored in the one or more memories 420. The system 400, the one or more processors 410, and/or the one or more memories 420 may be configured to, and/or define means for, obtaining leakage data associated with a plurality of circuits.

At block 310, the method 300 may identify a commutative circuit of a plurality of circuits, the commutative circuit being configured to receive a first input via a first terminal and a second input via a second terminal. For example, the system 400, the one or more processors 410 and/or the identification component 412 may identify a NAND gate, an AND gate, an XOR gate, an OR gate, an NOR gate, or a circuit having one or more commutative circuits. The system 400, the one or more processors 410, the identification component 412, and/or the one or more memories 420 may be configured to, and/or define means for, identifying a commutative circuit of a plurality of circuits, the commutative circuit being configured to receive a first input via a first terminal and a second input via a second terminal.

At block 315, the method 300 may identify a first leakage current associated with a first state of the commutative circuit and a second leakage current associated with a second state of the commutative circuit, the first leakage current being larger than the second leakage current. For example, the system 400, the one or more processors 410, the leakage identifier 414, and/or the one or more memories 420 may check the leakage state of the circuits in idle status. The system 400, the one or more processors 410, the leakage identifier 414, and/or the one or more memories 420 may be configured to, and/or define means for, identifying a first leakage current associated with a first state of the commutative circuit and a second leakage current associated with a second state of the commutative circuit, the first leakage current being larger than the second leakage current.

At block 320, the method 300 may switch the first input and the second input such that the commutative circuit receives the first input via the second terminal and the second input via the first terminal. For example, the system 400, the one or more processors 410, the configuration component 416, and/or the one or more memories 420 may use software to change switch the input to the circuit. The system 400, the one or more processors 410, the configuration component 416, and/or the one or more memories 420 may be configured to, and/or define means for, switching the first input and the second input such that the commutative circuit receives the first input via the second terminal and the second input via the first terminal.

Aspects of the present disclosure may include the method above, further comprising, priori to identifying the commutative circuit, obtaining leakage data associated with the plurality of circuits.

Aspects of the present disclosure may include any of the methods above, wherein identifying the commutative circuit includes identifying one or more of a NAND gate, an AND gate, an OR gate, a XOR gate, or a NOR gate.

Aspects of the present disclosure may include any of the methods above, wherein identifying the commutative circuit includes identifying a circuit that includes one or more of a NAND gate, an AND gate, an OR gate, a XOR gate, or a NOR gate.

Aspects of the present disclosure may include any of the methods above, wherein the circuit includes an adder or a multiplier.

Aspects of the present disclosure may include any of the methods above, wherein identifying the first leakage current comprises identifying the first leakage current through a first channel of a first transistor operating in a subthreshold regime of operation, identifying the second leakage current comprises identifying the second leakage current through a second channel of a second transistor operating in the subthreshold regime of operation, and the first transistor and the second transistor are in the commutative circuit.

Aspects of the present disclosure may include any of the methods above, wherein the first transistor and the second transistor are one or more of complimentary metal-oxide-silicon field effect transistors, metal-semiconductor field effect transistors, bipolar junction transistors, or junction field effect transistors.

Aspects of the present disclosure may include any of the methods above, wherein identifying the first leakage current comprises identifying the first leakage current caused by a first drain-source voltage difference and identifying the second leakage current comprises identifying the second leakage current caused by a second drain-source voltage difference.

Aspects of the present disclosure may include any of the methods above, wherein the first drain-source voltage difference is larger than the second drain-source voltage difference

Aspects of the present disclosure may include any of the methods above, wherein switching the first logical input signal and the second logical input signal does not change an output of the commutative circuit.

The above detailed description set forth above in connection with the appended drawings describes examples and does not represent the only examples that may be implemented or that are within the scope of the claims. The term “example,” when used in this description, means “serving as an example, instance, or illustration,” and not “preferred” or “advantageous over other examples.” The detailed description includes specific details for the purpose of providing an understanding of the described techniques. These techniques, however, may be practiced without these specific details. For example, changes may be made in the function and arrangement of elements discussed without departing from the scope of the disclosure. Also, various examples may omit, substitute, or add various procedures or components as appropriate. For instance, the methods described may be performed in an order different from that described, and various steps may be added, omitted, or combined. Also, features described with respect to some examples may be combined in other examples. In some instances, well-known structures and apparatuses are shown in block diagram form in order to avoid obscuring the concepts of the described examples.

Information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, computer-executable code or instructions stored on a computer-readable medium, or any combination thereof.

The various illustrative blocks and components described in connection with the disclosure herein may be implemented or performed with a specially-programmed device, such as but not limited to a processor, a digital signal processor (DSP), an ASIC, a FPGA or other programmable logic device, a discrete gate or transistor logic, a discrete hardware component, or any combination thereof designed to perform the functions described herein. A specially-programmed processor may be a microprocessor, but in the alternative, the processor may be any conventional processor, controller, microcontroller, or state machine. A specially-programmed processor may also be implemented as a combination of computing devices, e.g., a combination of a DSP and a microprocessor, multiple microprocessors, one or more microprocessors in conjunction with a DSP core, or any other such configuration.

The functions described herein may be implemented in hardware, software executed by a processor, firmware, or any combination thereof. If implemented in software executed by a processor, the functions may be stored on or transmitted over as one or more instructions or code on a non-transitory computer-readable medium. Other examples and implementations are within the scope and spirit of the disclosure and appended claims. For example, due to the nature of software, functions described above may be implemented using software executed by a specially programmed processor, hardware, firmware, hardwiring, or combinations of any of these. Features implementing functions may also be physically located at various positions, including being distributed such that portions of functions are implemented at different physical locations. Also, as used herein, including in the claims, “or” as used in a list of items prefaced by “at least one of” indicates a disjunctive list such that, for example, a list of “at least one of A, B, or C” means A or B or C or AB or AC or BC or ABC (i.e., A and B and C).

Computer-readable media includes both computer storage media and communication media including any medium that facilitates transfer of a computer program from one place to another. A storage medium may be any available medium that may be accessed by a general purpose or special purpose computer. By way of example, and not limitation, computer-readable media may comprise RAM, ROM, EEPROM, CD-ROM or other optical disk storage, magnetic disk storage or other magnetic storage devices, or any other medium that may be used to carry or store desired program code means in the form of instructions or data structures and that may be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The previous description of the disclosure is provided to enable a person skilled in the art to make or use the disclosure. Various modifications to the disclosure will be readily apparent to those skilled in the art, and the common principles defined herein may be applied to other variations without departing from the spirit or scope of the disclosure. Furthermore, although elements of the described aspects may be described or claimed in the singular, the plural is contemplated unless limitation to the singular is explicitly stated. Additionally, all or a portion of any aspect may be utilized with all or a portion of any other aspect, unless stated otherwise. Thus, the disclosure is not to be limited to the examples and designs described herein but is to be accorded the widest scope consistent with the principles and novel features disclosed herein.

What is claimed is:

1. A method of reducing leakage current, comprising:
identifying a commutative circuit of a plurality of circuits, the commutative circuit being configured to receive a first logical input signal via a first terminal and a second logical input signal via a second terminal;
identifying a first leakage current associated with a first state of the commutative circuit and a second leakage current associated with a second state of the commutative circuit, the first leakage current being larger than the second leakage current; and
switching, at a software level, the first logical input signal and the second logical input signal such that the commutative circuit receives the first logical input signal via the second terminal and the second logical input signal via the first terminal.

2. The method of claim 1, further comprising, priori to identifying the commutative circuit, obtaining leakage data associated with the plurality of circuits.

3. The method of claim 1, wherein identifying the commutative circuit includes identifying one or more of a NAND gate, an AND gate, an OR gate, a XOR gate, or a NOR gate.

4. The method of claim 1, wherein identifying the commutative circuit includes identifying a circuit that includes one or more of a NAND gate, an AND gate, an OR gate, a XOR gate, or a NOR gate.

5. The method of claim 1, wherein the circuit includes an adder or a multiplier.

6. The method of claim 1, wherein:
identifying the first leakage current comprises identifying the first leakage current through a first channel of a first transistor operating in a subthreshold regime of operation;
identifying the second leakage current comprises identifying the second leakage current through a second channel of a second transistor operating in the subthreshold regime of operation; and
the first transistor and the second transistor are in the commutative circuit.

7. The method of claim 6, wherein the first transistor and the second transistor are one or more of complimentary metal-oxide-silicon field effect transistors, metal-semiconductor field effect transistors, bipolar junction transistors, or junction field effect transistors.

8. The method of claim 6, wherein:
identifying the first leakage current comprises identifying the first leakage current caused by a first drain-source voltage difference; and
identifying the second leakage current comprises identifying the second leakage current caused by a second drain-source voltage difference.

9. The method of claim 8, wherein the first drain-source voltage difference is larger than the second drain-source voltage difference.

10. The method of claim 1, wherein switching the first logical input signal and the second logical input signal does not change an output of the commutative circuit.

11. A non-transitory computer readable medium having instructions that, when executed by one or more processors, cause the one or more processors to:
identify a commutative circuit of a plurality of circuits, the commutative circuit being configured to receive a first logical input signal via a first terminal and a second logical input signal via a second terminal;
identify a first leakage current associated with a first state of the commutative circuit and a second leakage current associated with a second state of the commutative circuit, the first leakage current being larger than the second leakage current; and
switch, at a software level, the first logical input signal and the second logical input signal such that the commutative circuit receives the first logical input signal via the second terminal and the second logical input signal via the first terminal.

12. The non-transitory computer readable medium of claim 11, further comprising instructions for, priori to identifying the commutative circuit, obtaining leakage data associated with the plurality of circuits.

13. The non-transitory computer readable medium of claim 11, wherein the instructions for identifying the commutative circuit includes instructions for identifying one or more of a NAND gate, an AND gate, an OR gate, a XOR gate, or a NOR gate.

14. The non-transitory computer readable medium of claim 11, wherein the instructions for identifying the commutative circuit includes instructions for identifying a circuit that includes one or more of a NAND gate, an AND gate, an OR gate, a XOR gate, or a NOR gate.

15. The non-transitory computer readable medium of claim 11, wherein the circuit includes an adder or a multiplier.

16. The non-transitory computer readable medium of claim 11, wherein:
the instructions for identifying the first leakage current comprises instructions for identifying the first leakage current through a first channel of a first transistor operating in a subthreshold regime of operation;
the instructions for identifying the second leakage current comprises instructions for identifying the second leakage current through a second channel of a second transistor operating in the subthreshold regime of operation; and
the first transistor and the second transistor are in the commutative circuit.

17. The non-transitory computer readable medium of claim 16, wherein the first transistor and the second transistor are one or more of complimentary metal-oxide-silicon field effect transistors, metal-semiconductor field effect transistors, bipolar junction transistors, or junction field effect transistors.

18. The non-transitory computer readable medium of claim 16, wherein:
the instructions for identifying the first leakage current comprises instructions for identifying the first leakage current caused by a first drain-source voltage difference; and
the instructions for identifying the second leakage current comprises instructions for identifying the second leakage current caused by a second drain-source voltage difference.

19. The non-transitory computer readable medium of claim 18, wherein the first drain-source voltage difference is larger than the second drain-source voltage difference.

20. The non-transitory computer readable medium of claim 10, wherein switching the first logical input signal and the second logical input signal does not change an output of the commutative circuit.
